(19) United States
(12) Patent Application Publication
(10) Pub. No.: US 2021/0126124 A1
(43) Pub. Date: Apr. 29, 2021

(54) TERMINATION OF MULTIPLE STEPPED OXIDE SHIELDED GATE TRENCH MOSFET

(71) Applicant: Nami MOS CO., LTD., New Taipei City (TW)

(72) Inventor: Fu-Yuan HSIEH, New Taipei City (TW)

(73) Assignee: Nami MOS CO., LTD., New Taipei City (TW)

(21) Appl. No.: 16/666,500

(22) Filed: Oct. 29, 2019

(51) Int. Cl. H01L 29/78; H01L 23/552; H01L 29/06; H01L 29/66; H01L 29/417; H01L 29/45

(52) U.S. Cl. CPC H01L 29/7811; H01L 23/552; H01L 29/7813; H01L 21/26586; H01L 29/66734; H01L 29/41741; H01L 29/456; H01L 29/0623

(57) ABSTRACT

A shielded gate trench MOSFET with multiple stepped oxide (MSO) structure surrounding the shielded gate in termination area is disclosed. The inventive structure can reduce specific on-resistance and support enough breakdown voltage, simultaneously. The device structure termination is achieved using angle implant of N and P columns.

### FIELD OF THE INVENTION

This invention relates generally to the cell structure, device configuration and fabrication process of power semiconductor devices. More particularly, this invention relates to a novel and improved cell structure, device configuration and improved fabrication process of a shielded gate trench MOSFET (Metal Oxide Semiconductor Field Effect Transistor).

### BACKGROUND OF THE INVENTION

Please refer to FIG. 1A for a conventional Shielded Gate Trench MOSFET structure with termination, wherein thick oxide surrounding the shielded gate is uniform along trench sidewall. A single shielded gate surrounded with the thick oxide in termination area is served as a field plate to maintain breakdown voltage (BV) in the termination equal or higher than active area.

Please refer to FIG. 2B for a new shielded gate trench MOSFET (U.S. Pat. No. 9,716,009) having multiple stepped oxide (MSO) surrounding the shielded gate which has significant lower specific on-resistance (Rsp) than the conventional shielded gate trench MOSFET, e.g. 25% lower Rsp for 100V.

However, the MSO shielded gate MOSFET may encounters low BV in termination area as a result of thin oxide surrounding top region of shielded gate, which may not support enough BV.

Therefore, there is still a need in the art of the semiconductor power device, particularly for shielded gate trench MOSFET design and fabrication, to provide a novel cell structure, device configuration that would resolve the difficulties and design limitations mentioned above to achieve lower specific on-resistance (Rsp) and support enough BV in the MOSFET, simultaneously.

### SUMMARY OF THE INVENTION

The present invention provides a shielded gate trench MOSFET with multiple stepped oxide surrounding the shielded gate in termination area, to achieve lower specific on-resistance (Rsp) and support enough B, simultaneously. N column in active area and N/P columns in termination area is formed by angle As or Phosphorus/Boron implants implantation into the trench sidewall followed by diffusion procedure.

In one aspect, the present invention features a shielded gate trench MOSFET comprising: a substrate of a first conductivity type; an epitaxial layer of said first conductivity type onto said substrate, wherein the epitaxial layer has a lower doping concentration than said substrate; a plurality of gate trenches starting from a top surface of the epitaxial layer and extending downward into the epitaxial layer in an active area; a first thick gate insulation layer formed along lower part of trench sidewalls of each of the gate trenches with a MSO structure, of which oxide thickness decreasing in multiple steps from bottom of the gate trenches toward top; a shielded electrode formed within each of said gate trenches and surrounded by said first MSO gate insulation layer in the lower portion of each of the gate trenches; a second gate insulation layer as gate oxide formed at least along trench sidewalls of an upper portion of each of the gate trenches and upper sidewalls of the shielded electrode above the first gate insulation layer, the second gate insulation layer having a thinner thickness than the first gate insulation layer; a gate electrode formed adjacent to the second gate insulation layer and above a third gate insulation layer between the shielded electrode and the gate electrode in the upper portion of each of the gate trenches; the gate electrode and the shielded electrode are doped poly-silicon layers; an oxide charge balance region of the first conductivity and having a higher doping concentration than the epitaxial layer, disposed in a mesa between two adjacent the gate trenches; a body region of a second conductivity type formed in the mesa, above a top surface of the oxide charge region; and a source region of the first conductivity type formed near a top surface of the body region and adjacent to the gate electrodes; and a junction balance region is formed near edge of the active area in a termination area consist of a first doped column region of the first conductivity type having a higher doping concentration than the epitaxial layer, and a second doped column region of the second conductivity type adjacent to the first doped column region.

Preferred embodiments include one or more of the following features: the oxide charge balance region has a higher doping concentration near trench sidewalls of the gate trenches than in the center of the mesa; the trench MOSFET further comprises a trenched source-body contact filled with a contact metal plug and penetrating through the source region and extending into the body region; and a body contact doped region of the second conductivity type within the body region and surrounding at least bottom of the trenched source-body contact underneath the source region, wherein the body contact doped region has a higher doping concentration than the body region; and the contact metal plug is a tungsten metal layer padded by a barrier metal layer of Ti/TiN or Co/TiN; the present invention further comprises a termination area which comprising a guard ring connected with the source region and the body region, wherein the guard ring of the second conductivity type have junction depths greater than the body region; the present invention further comprises a termination area which comprising a termination area which comprising multiple floating body regions having floating voltage in a termination area wherein the multiple floating body regions having same conductivity type and junction depths as the body regions, formed simultaneously as the body regions; the present invention further comprises a plurality of trenched source-body contact formed in an active area, each filled with a contact metal plug, penetrating through the source regions and the body regions and extending into the oxide charge balance region in the mesa; and a body contact doped region of the second conductivity type formed along an upper portion of sidewalls of the trenched source-body contacts below the source regions, wherein the body contact doped region has a higher doping concentration than the body regions; and a Schottky diode doped region surrounding bottoms and a lower portion of sidewalls of the trenched source-body contacts below the body contact doped region, wherein the Schottky diode doped region has either the first or the second conductivity doping type; and the contact metal plug is a tungsten metal layer padded by a barrier metal layer of Ti/TiN or Co/TiN.

The present invention further features a method for manufacturing a shielded gate trench MOSFET comprising the steps of: (a) growing an epitaxial layer of a first conductivity type upon a substrate of the first conductivity type, wherein the epitaxial layer has a lower doping concentration than the substrate; (b) forming a hard mask oxide onto a top surface of the epitaxial layer for definition of a plurality of gate trenches; (c) applying a trench mask on the block layer; (d) forming a plurality of gate trenches, and mesas between two adjacent gate trenches in the epitaxial layer by etching through open regions in the block layer; (e) keeping the block layer substantially covering the mesas after formation of the trenches to block sequential angle ion implantation into top surfaces of the mesas: (f) growing a screen oxide along an inner surface of the trenches; (g) carrying out an angle Ion Implantation of a second conductivity type dopant into the mesas through trench sidewalls of the gate trenches to form a plurality of first doped column regions in the mesas and adjacent to sidewalls of the gate trenches; (h) carrying out an angle Ion Implantation of the first conductivity type dopant into the mesas through trench sidewalls of the gate trenches to form a plurality of second doped column regions adjacent to the sidewalls of the gate trenches and in parallel with the first doped column regions; (i) diffusing both the first conductivity type dopant and the second conductivity type dopant into the mesas simultaneously to form the second doped column region between two adjacent gate trenches in the active area, and the first doped and the second doped column regions in termination area; (j) forming a thick oxide layer as the first insulation layer along inner surfaces of the gate trenches by thermal oxide growth or CVD; (k) depositing a first doped poly-silicon layer filling the gate trenches to serve as sacrificial layer, and etching it back to first depth; (l) etch back the thick oxide layer; (m) performing second etch back of the first poly-silicon layer and second oxide etch back to second depth; (n) performing third etch back of the first doped poly-silicon layer, and third oxide etch back to third depth; (o) etching remaining first doped poly-silicon layer; (p) growing another oxide layer as the second insulation layer along upper inner surfaces of the gate trenches and top surfaces of the epitaxial layer; (q) depositing a second doped poly-silicon layer filling the gate trenches and etching it back by CMP (Chemical Mechanical Polishing) and plasma etch to leave the second doped poly-silicon layer in lower portion of the gate trenches as shielded electrode, followed by a third insulation layer growth; (r) depositing a third poly-silicon conductive layer filling the upper portion of the gate trenches, and etching it back by CMP to serve as gate electrodes; (s) applying a body mask onto a top surface of the epitaxial layer, carrying out a body implantation of the second conductivity type dopant and a step of body diffusion to form a body region; (t) removing the body mask and applying a source mask onto top surface of the epitaxial layer, carrying out Ion Implantation of the first conductivity type dopant and diffusion to form a source region; (u) removing the source mask and depositing a contact interlayer onto a top surface of the epitaxial layer, applying a contact mask and etching a contact trench penetrating the contact interlayer, the source region and extending into the body region or into the epitaxial layer.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is a cross-sectional view of a shielded gate trench MOSFET of a prior art.

FIG. 1B is a cross-sectional view of a shielded gate trench MOSFET of another prior art.

FIG. 2 is a cross-sectional view of a preferred embodiment according to the present invention.

FIG. 3 is a cross-sectional view of another preferred embodiment according to the present invention.

FIG. 4 is a cross-sectional view of another preferred embodiment according to the present invention.

FIG. 5 is a cross-sectional view of another preferred embodiment according to the present invention.

FIG. 6 is a cross-sectional view of another preferred embodiment according to the present invention.

FIG. 7 is a cross-sectional view of another preferred embodiment according to the present invention.

FIG. 8 is a cross-sectional view of another preferred embodiment according to the present invention.

FIGS. 9A˜9N are a serial of side cross-sectional views for showing the processing steps for fabricating the shielded gate trench MOSFET as shown in FIG. 6.

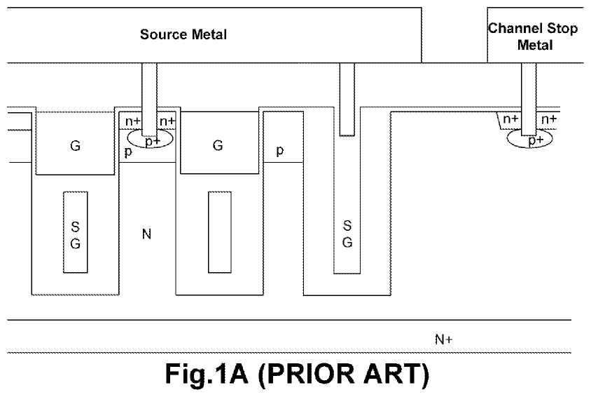

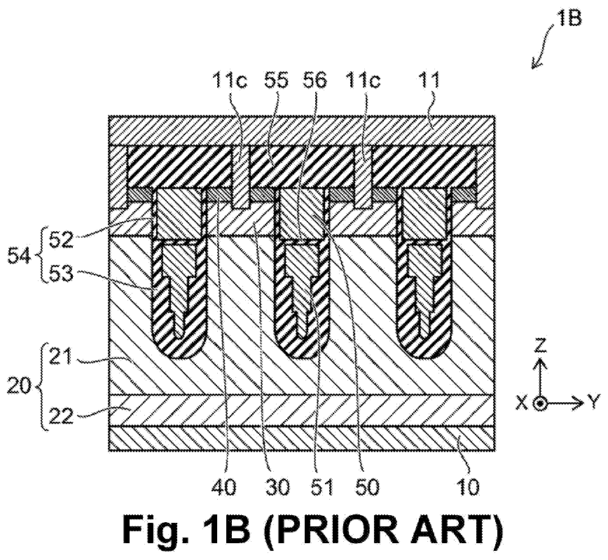

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

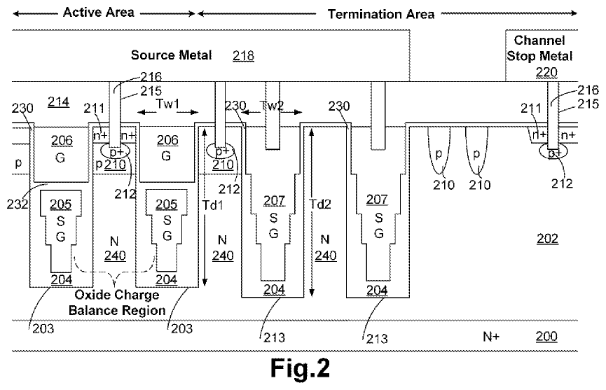

Please refer to FIG. 2A for a preferred embodiment of this invention where an N-channel shielded gate trench MOSFET having MSO structure with multiple floating P bodies in a termination area is formed in an N type epitaxial layer 202 onto an N+ substrate 200. A plurality of gate trenches 203 in active area and gate trenches 213 in termination area are formed starting from a top surface of the N type epitaxial layer 202 and vertically down extending, not reaching the interface of the N type epitaxial layer 202 and the N+ substrate 200. Into each of the trenches 203, an MSO structure 204 is formed by repeating the oxide etching for three times, which is similar to smooth gradient oxide, a doped poly-silicon layer is deposited filling a lower portion of the trenches 203 to serve as a shielded electrode 205 padded by the MSO structure 204. Into an upper portion of each of the gate trenches 203, another doped poly-silicon layer is deposited onto the third insulation layer 232 close to the second insulation layer 230 to serve as a gate electrode 206. The gate electrode 206 and shielded electrode 205 is isolated from each other by the third insulation layer 232. Between the two adjacent trenches 203, an N type column region 240 is formed adjacent to sidewalls of the trenches. Onto a top surface of the N type column regions 240 in active area, a p body region 210 is formed with an n+ source region 211 near its top surface and flanking the trenches 203. Furthermore, in the p body region 210, a p+ body contact doped region 212 is formed surrounding at least bottom of the trenched source-body contact 215 underneath the n+ source region 211 to reduce the contact resistance between the p body region 210 and the contact metal plug 216 in the trenched source-body contact 215. Into each of the trenches 213, an MSO structure 204 is formed by repeating the oxide etching for three times, which is the same as that in gate trenches 203. A second insulation layer as gate oxide 230 is then deposited along the inner surfaces of the gate trenches and on the surfaces of the epitaxial layer 202, a doped poly-silicon layer is then deposited filling the trenches 213 to serve as a shielded electrode 207 padded by the MSO structure 204. In the N type doped column regions 240 outside the edge of active area including the termination area, a p+ body contact doped region 212 is formed surrounding at least bottom of the trenched source-body contact 215 without n+ source region. Termination area in the present invention is formed by at least two shielded electrode 207 served as trench gate field plates with trench width and depth equal to or greater than active area (Tw1≥Tw2 and Td2≥Td1). The N-channel shielded gate trench MOSFET further comprises multiple floating P body regions 210 having floating voltage in a termination area. Besides, the source metal 218 is formed onto the contact interlayer 214 and connected with the contact metal plug 216, penetrating through the contact interlayer 214 to contact with the n+ source region 211, the p body region 210 and the p+ body contact doped region 212 in the active area, or only contact with the p body region 210 and the p+ body contact doped region 212 around outside of active area in the termination area, or the shielded electrode 207 by the contact metal plug 216. The channel stop metal 220 is formed onto the contact interlayer 214 and connected with contact metal plug 216 penetrating through the contact interlayer 214 to contact with the n+ source region 211, the epitaxial layer 202, and a p+ body contact doped region 212 in the termination area. In the present invention, oxide charge balance region including the first insulation layer 204 and the N doped mesa 240 in the active area.

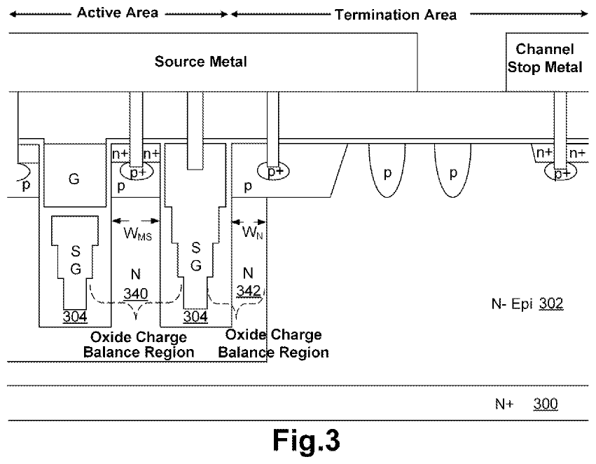

FIG. 3 shows a cross-sectional view of another trench MOSFET according to the present invention, wherein the N columns in active and termination area are formed by angle As or Phosphorus implantation into trench sidewall, which is followed by diffusion procedure to form the N columns 340 and 342 in N− epitaxial layer. The termination area further comprises edge N column 342 and multiple P body floating rings. In the present invention, oxide charge balance regions including the first insulation layer 304 and the N doped mesa 340 in active area, and the first insulation layer 304 and the edge N doped mesa 342 in termination area.

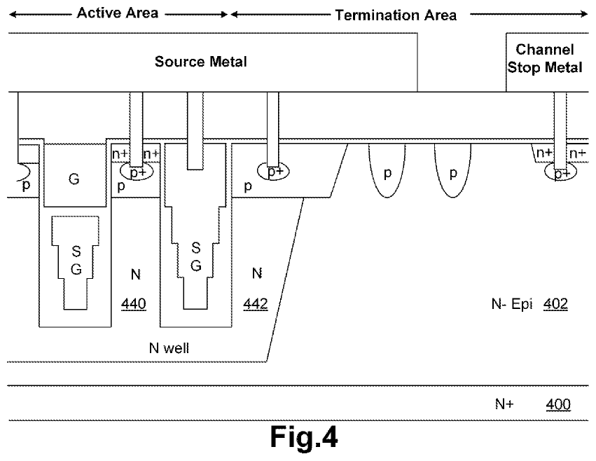

FIG. 4 shows another preferred embodiment of the present invention, which is similar to the structure in FIG. 3 except that, in FIG. 4, edge of the N well 442 is tilt while the N column 342 in FIG. 3 is vertically downward. In this invention, the N well 440 and 442 is formed by As or Phosphorus implantation from top surface of an N− epitaxial layer, which is followed by diffusion procedure to form oxide charge balance regions in active and termination areas. The termination area further comprises the N well 442 and multiple P body floating rings or a P type guard ring with junction depth deeper than the P body. The N well junction depth is shallower or deeper than the gate trenches.

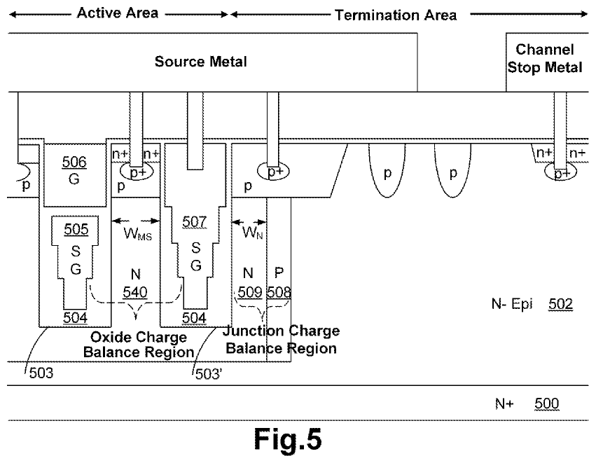

FIG. 5 shows another preferred embodiment of the present invention, which is similar to the structure in FIG. 3 except that, termination area of FIG. 3 comprises edge N column 342, while that in FIG. 5 comprises N column 509 and P column 508 in parallel. In the present invention, oxide charge balance region including the first insulation layer 504 and the N doped mesa 540 in the active area, while junction charge balance region including the N column 509 and P column 508 in termination area are achieved by reducing mesa width W_{MS} less than twice of N column diffusion width W_{N}(W_{MS}<2 W_{N}). Therefore, Lower Rsp and better avalanche capability is achieved. The mesa 540 only has net N doped charge because the N type doped column (NC) overrides P type doped column (PC) after NC/PC diffusion.

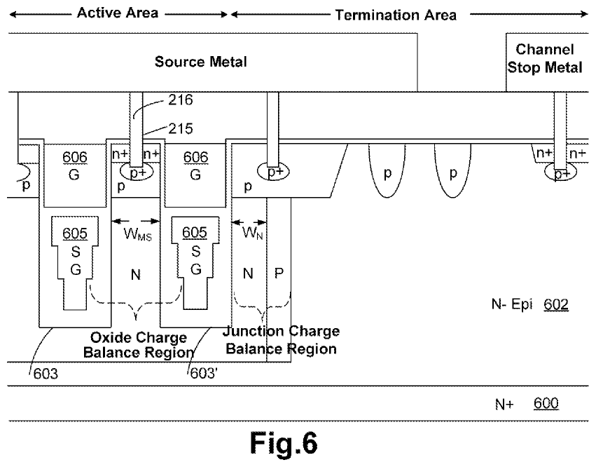

FIG. 6 shows another preferred embodiment of the present invention, which is similar to the structure in FIG. 5 except that, in FIG. 6, the edge trench 603′ has dual electrodes 605 and 606, while the edge trench 503′ in FIG. 5 consist of a single electrode 507.

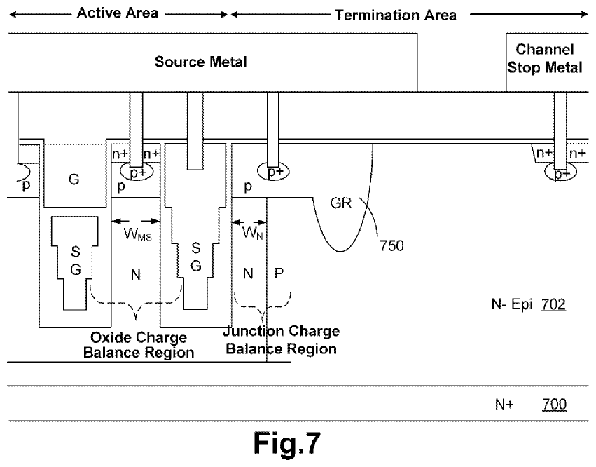

FIG. 7 shows another preferred embodiment of the present invention, which is similar to the structure in FIG. 5 except that, the N-channel shielded gate trench MOSFET in FIG. 7 comprises a different termination area comprising a P type guard ring 750 (GR, as illustrated in FIG. 7) having junction depth greater than the P body regions.

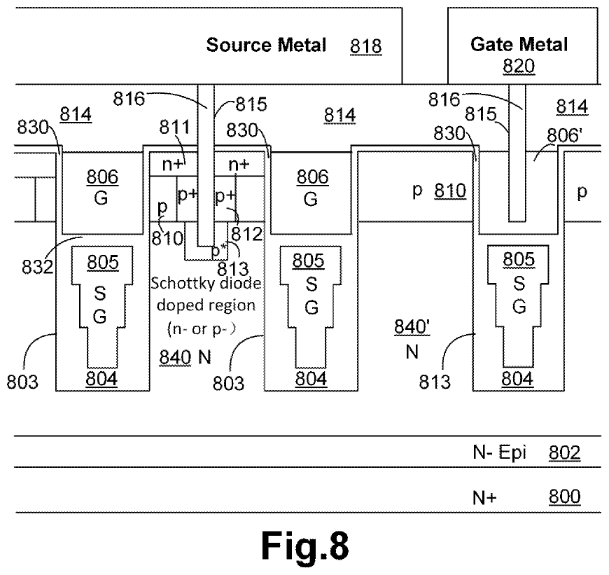

FIG. 8 shows another preferred embodiment of the present invention, wherein an N-channel MSO shielded gate trench MOSFET with an embedded Schottky diode is formed in an N type doped column 840 in active area. A plurality of gate trenches 803, and 813 are formed starting from a top surface of the N− epitaxial layer 802 and extending downward into the N− epitaxial layer 802, not reaching the interface of the N− epitaxial layer 802 and the N+ substrate 800. Into each of the trenches 803, a MSO structure 804 is formed by repeating the oxide etching for three times, which is similar to smooth gradient oxide, a doped poly-silicon layer is deposited filling a lower portion of the trench 803 and 813 to serve as a shielded electrode 805 padded by a first insulation MSO layer 804. Into an upper portion of each of the trenches 803 and 813, another doped poly-silicon layer is deposited to serve as gate electrodes 806 close to the second insulation layer 830 onto the third insulation layer 832, isolating from the shielded electrode 805. A plurality of P body regions 810 are formed in an upper portion of the N− epitaxial layer 802 and extending between two adjacent gate trenches. A plurality of n+ source regions 811 are formed near a top surface of the P body regions 810 in an active area. A plurality of trenched source-body contacts 815 each filled with a contact metal plug 816 are penetrating through a contact interlayer 814, the n+ source regions 811, the P body regions 810 and extending into the N type doped column region 840 in the active area, wherein the trenched source-body contacts 815 have a depth shallower than the gate trenches but deeper than the P body regions 810. The trench MOSFET has double P type doped implant regions along the trenched source-body contacts 815 in the active area: the first p+ body contact doped implant region 812 is formed along an upper portion of sidewalls of the trenched source-body contacts 815 and below the n+ source regions 811 in the P body regions 810 to reduce body contact resistance; a second Schottky diode doped implant region 813 is surrounding bottom and a lower portion of the sidewalls of each of the trenched source-body contacts 815 underneath the first p+ body contact doped implant region 812. The second Schottky diode doped implant region 813 has either n− or p− doping type (n− or p−, Schottky diode doped region as illustrated in FIG. 8) depending on the second implant dose. As the lower portion of the trenched source-body contacts 815 and the interfaced second Schottky diode doped implant region 813 together form the embedded Schottky diodes, the embedded Schottky diodes formed within the second implant regions 813 along trench sidewalls and bottom of lower portion of trenched source-body contacts, thus avoiding the high leakage current and enhancing pinch-off effect. According to this embodiment, the contact metal plug 816 can be implemented by a tungsten metal layer padded by a barrier metal layer of Ti/TiN or Co/TiN. A plurality of trenched source-body contacts 815 each filled with a contact metal plug 816 are penetrating through a contact interlayer 814 and extending into N type doped column region 840 or the gate electrode 806′, to connect with the source metal 818 and gate metal 820, respectively.

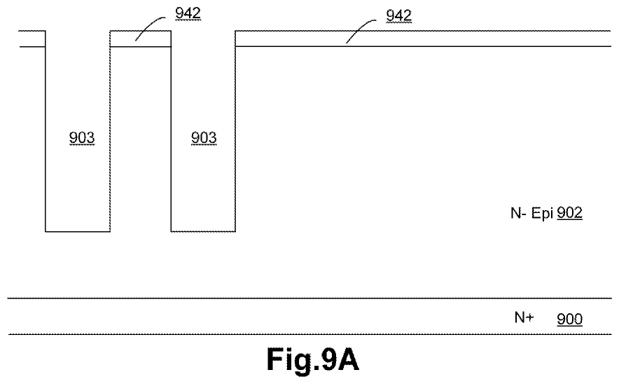

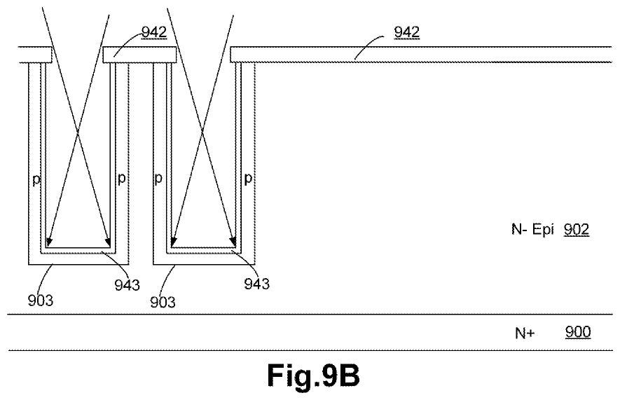

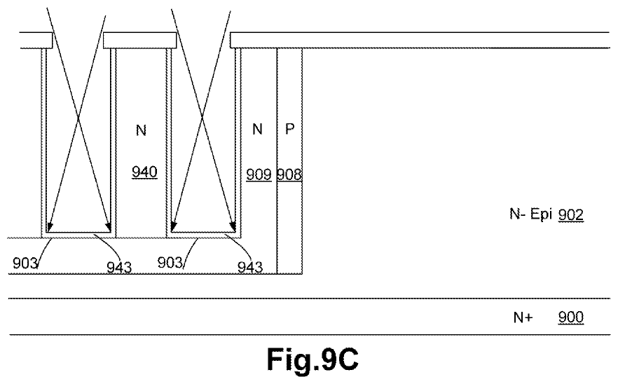

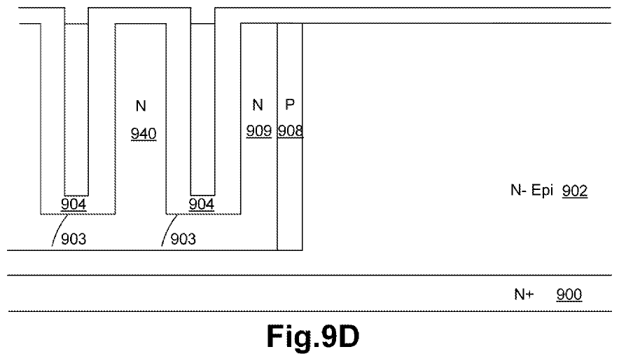

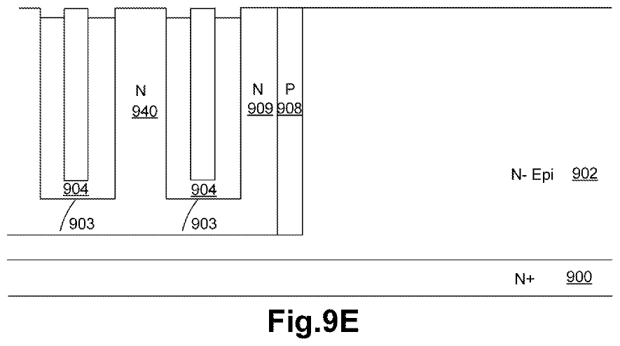

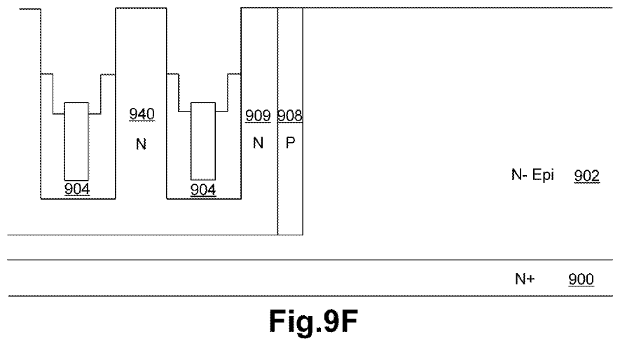

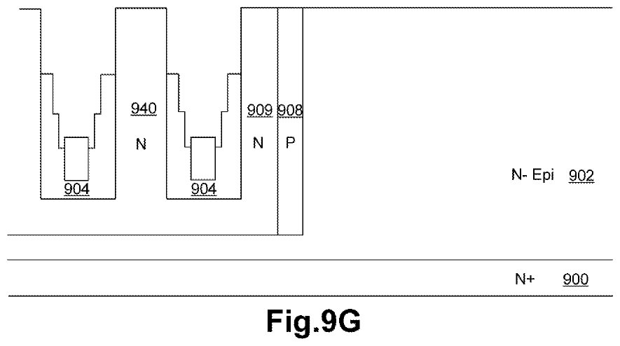

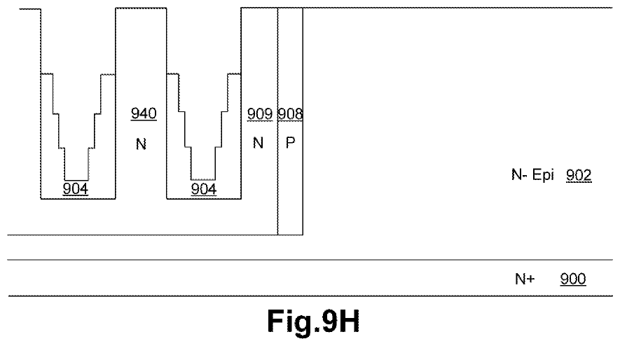

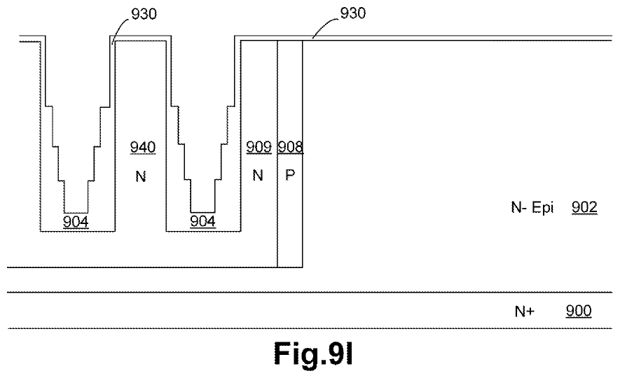

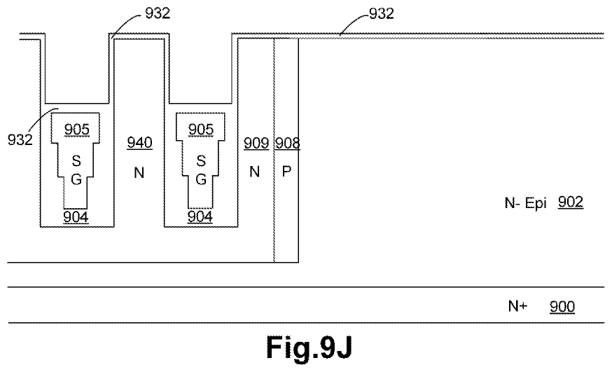

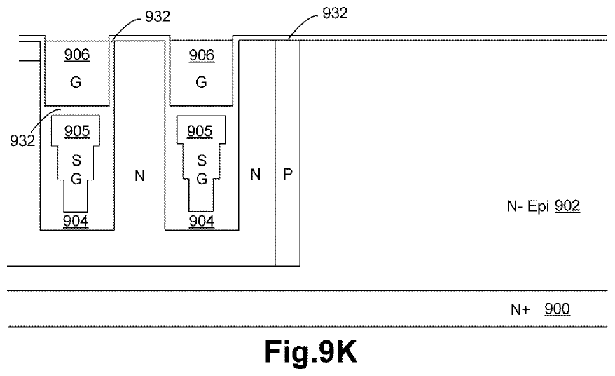

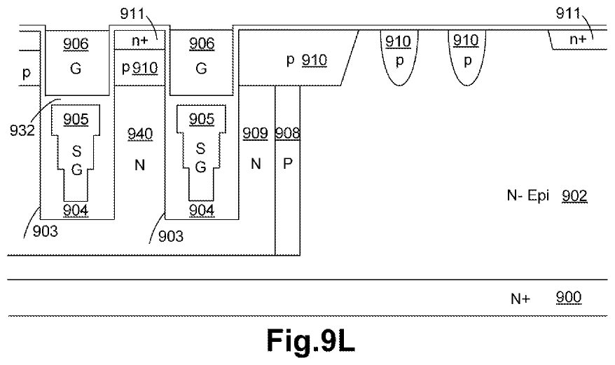

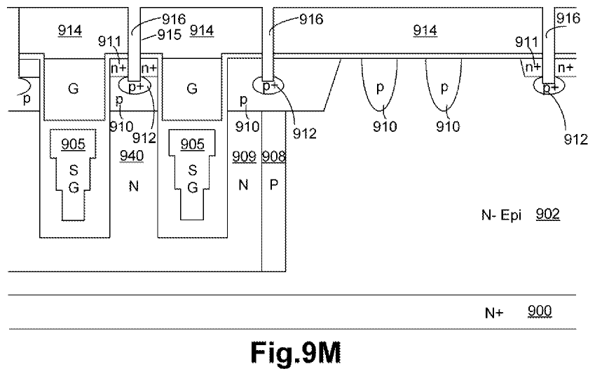

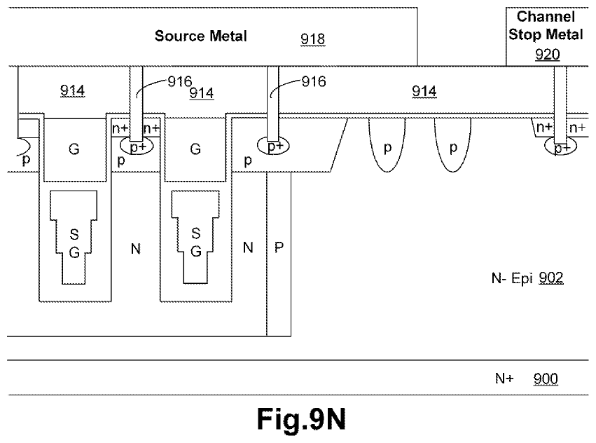

FIGS. 9A-9N are a serial of exemplary steps that are performed to form the inventive shielded gate trench MOSFET in FIG. 6. In FIG. 9A, an N− epitaxial layer 902 is formed onto an N+ substrate 900, wherein the N+ substrate 900 has a higher doping concentration than the N− epitaxial layer 902. Next, an oxide layer 942 is formed onto a top surface of the N− epitaxial layer 902. Then, after a trench mask (not shown) is applied onto the oxide layer 942, a plurality of trenches 903 are etched penetrating through the oxide layer 942, the N− epitaxial layer 902 and above the interface between the N− epitaxial layer 902 and N+ substrate 900 by successively dry oxide etch and dry silicon etch.

In FIG. 9B, an isotropic Si etch is performed to eliminate the plasma damage introduced during opening the gate trenches 903. The oxide layer 942 is still substantially remained on the mesas after the isotropic etch to block sequential angle ion implantations into top surfaces of the mesas. After that, a screen oxide 943 is grown along inner surfaces of the gate trenches 903. Then, an angle Ion Implantation of boron dopant is carried out to form a plurality of P type first doped column regions with column shape in the mesas and termination area, and adjacent to sidewalls of the gate trenches 903 within the N− epitaxial layer 902.

In FIG. 9C, another angle Ion Implantation of Arsenic or Phosphorus dopant is carried out, and followed by a diffusion step. As a result of W_{MS}<2 W_{N}, the mesa area only has net N doped column 940 because the NC overrides PC after NC/PC diffusion step, while in termination area, an N type second doped column region 909 is in parallel surrounded with a P type first doped column region 908.

In FIG. 9D, the oxide layer 942 and the screen oxide 943 are removed away. A first thick insulation layer 904 is formed lining the inner surfaces of the trenches 903 by thermal oxide growth or thick oxide deposition. Then, a first doped poly-silicon layer as sacrificial layer is deposited onto the first insulation layer 904 filling the trenches 903, and is etched back to its first depth by poly CMP and plasma etch.

In FIG. 9E, the first insulation layer 904 is etched back to the first depth.

In FIG. 9F, a second poly-silicon layer etch back is carried out, and a second insulation layer 904 etch back is also carried out to the second depth.

In FIG. 9Q a third poly-silicon layer etch back is carried out, and third insulation layer 904 etch back is carried out to the third depth.

In FIG. 9H, a fourth poly-silicon layer is etched back completely.

In FIG. 9I, a second insulation layer 930 is formed along inner sidewalls of the trenches and on top surface of the N− epitaxy layer 902.

In FIG. 9J, a second doped poly silicon layer is deposited to fill the trenches 903 and in contact with the first insulation layer 904 and the second insulation layer 930, and is then etched back by CMP and plasma etch to form the shielded electrode 905. Then, the second insulation layer 930 is removed from upper sidewall of gate trench, and a third insulation layer as gate oxide 932 is grown, to insulate the gate electrode from the epitaxial layer and the shielded electrode.

In FIG. 9K, a third doped poly silicon layer is deposited onto the third insulation layer 932 filling an upper portion of the trenches to serve as a gate electrode 906. Next, the gate electrode 906 is etched back by CMP or Plasma Etch.

In FIG. 9L, after applying a body mask (not shown), a step of Ion Implantation with P type dopant is carried out and followed by a diffusion step to form a p body region 910 between every two adjacent trenches 903 and onto the N type first doped column regions 909 and the P type second doped column regions 908, and moreover, multiple p body regions 910 having floating voltage are formed in termination area. Then, after applying a source mask (not shown), a step of Ion Implantation with N type dopant is carried out to form an n+ source region 911 near a top surface of the P body region 910 and flanking the trenches 903, while another n+ source region 911 is formed in the top surface of the N− epitaxy layer 902 in the termination area. Furthermore, the n+ source region 911 has a higher doping concentration than the N− epitaxial layer 902.

In FIG. 9M, an oxide layer is deposited onto the top surface of the N− epitaxial layer 902 to serve as a contact interlayer 914. Then, after applying a contact mask (not shown) onto the contact interlayer 914, trenched source-body contacts 915 are formed by successively dry oxide etching and dry silicon etching. The trenched source-body contact 915 are penetrating through the contact interlayer 914, the n+ source region 911 and extending into the p body region 910 in an active area, or through the contact interlayer 914 and extending into the p body region 910, and the epitaxial layer 902 in the termination area. Next, a BF2 Ion Implantation is performed to form a p+ body contact doped region 912 within the p body region 910 or the N− epitaxy layer 902 in the termination area, and surrounding at least bottom of each source-body contact 915. The trenched source-body contacts are filled with metal plug 916 comprising a tungsten metal layer padded by a barrier metal layer of Ti/TiN or Co/TiN.

In FIG. 9N, a metal layer comprising Al alloys padded with a resistance-reduction layer Ti or Ti/TiN is deposited onto a top surface of the contact interlayer 914 and connected with the metal plug 916. Then, after applying a metal mask, the metal layer is etched to function as a source metal 918 and channel stop metal 920, respectively.

Although the present invention has been described in terms of the presently preferred embodiments, it is to be understood that such disclosure is not to be interpreted as limiting. Various alternations and modifications will no doubt become apparent to those skilled in the art reading the above disclosure. Accordingly, it is intended that the appended claims be interpreted as covering all alternations and modifications as fall within the true spirit and scope of the invention.

What is claimed is:

1. A trench MOSFET comprising:
a substrate of a first conductivity type;
an epitaxial layer of said first conductivity type onto said substrate, said epitaxial layer having a lower doping concentration than said substrate;
a plurality of gate trenches formed from a top surface of said epitaxial layer and extending downward into said epitaxial layer in an active area;
a multiple stepped oxide (MSO) as a first insulation layer formed in said lower part of each of said gate trenches; said MSO having non-uniform oxide thickness along sidewall of said gate trenches and said oxide thickness of said MSO decreasing in multiple steps from bottom of said gate trenches toward top.
a shielded electrode formed within said lower portion each of said gate trenches and surrounded by said MSO;
a second insulation layer as gate oxide formed along trench sidewalls of an upper portion of each of said gate trenches, said second gate insulation layer having a thickness thinner than said MSO;
a gate electrode formed within said upper portion of each of said gate trenches and surrounded by said second insulation layer, wherein said gate electrode and shielded electrode insulated from each other by a third insulation layer;
said gate electrode and said shielded are doped poly-silicon layers;
an implanted oxide charge balance region of said first conductivity and having a higher doping concentration than said epitaxial layer, disposed in a mesa between two adjacent said gate trenches;
a body region of a second conductivity type formed in said mesa, above a top surface of said oxide charge region; and
a source region of said first conductivity type formed near a top surface of said body region and adjacent to said gate electrode.

2. The trench MOSFET of claim 1 further comprising an angle implanted junction balance region formed near edge of said active area in a termination area consist of a first doped column region of said first conductivity type having a higher doping concentration than said epitaxial layer, and a second doped column region of said second conductivity type adjacent to said first doped column region.

3. The trench MOSFET of claim 1 further comprising an angle implanted oxide balance region formed near edge of said active area in a termination area consist of a first doped column region of said first conductivity type having a higher doping concentration than said epitaxial layer.

4. The trench MOSFET of claim 1, wherein said angle implanted oxide charge balance region has a higher doping concentration near trench sidewalls of said gate trenches than in said center of said mesa.

5. The trench MOSFET of claim 1 further comprising a trenched source-body contact filled with a contact metal plug and penetrating through said source region and extending into said body region; and a body contact doped region of said second conductivity type within said body region and surrounding at least bottom of said trenched source-body contact underneath said source region, wherein said body contact doped region has a higher doping concentration than said body region; and
said contact metal plug is a tungsten metal layer padded by a barrier metal layer of Ti/TiN or Co/TiN.

6. The trench MOSFET of claim 1 wherein said termination further comprising a guard ring connected with said source region and said body region, wherein said guard ring of said second conductivity type have junction depths greater than said body region.

7. The trench MOSFET of claim 1 wherein said termination further comprising a termination area which comprising multiple floating body regions having floating voltage in a termination area wherein said multiple floating body regions having same conductivity type and junction depths as said body regions, formed simultaneously as said body regions.

8. The trench MOSFET of claim 1 further comprising a plurality of trenched source-body contact formed in an active area, each filled with a contact metal plug, penetrating through said source regions and said body regions and extending into said oxide charge balance region in said mesa; and
a body contact doped region of said second conductivity type formed along an upper portion of sidewalls of said trenched source-body contacts below said source regions, wherein said body contact doped region has a higher doping concentration than said body regions; and a Schottky diode doped region surrounding bottoms and a lower portion of sidewalls of said trenched source-body contacts below said body contact doped region, wherein said Schottky diode doped region has either said first or said second conductivity doping type; and
said contact metal plug is a tungsten metal layer padded by a barrier metal layer of Ti/TiN or Co/TiN.

9. The trench MOSFET of claim 1, wherein trench bottoms of said gate trenches are above a common interface between said substrate and said epitaxial layer.

10. The trench MOSFET of claim 1, wherein said gate trenches further touch or extend into said substrate.

11. A trench MOSFET comprising:
a substrate of a first conductivity type;
an epitaxial layer of said first conductivity type onto said substrate, said epitaxial layer having a lower doping concentration than said substrate;
a plurality of gate trenches formed from a top surface of said epitaxial layer and extending downward into said epitaxial layer in an active area;
a multiple stepped oxide (MSO) as a first insulation layer formed in said lower part of each of said gate trenches; said MSO having non-uniform oxide thickness along sidewall of said gate trenches and said oxide thickness of said MSO decreasing in multiple steps from bottom of said gate trenches toward top.
a shielded electrode formed within said lower portion each of said gate trenches and surrounded by said MSO;
a second insulation layer as gate oxide formed along trench sidewalls of an upper portion of each of said gate trenches, said second gate insulation layer having a thickness thinner than said MSO;
a gate electrode formed within said upper portion of each of said gate trenches and surrounded by said second insulation layer, wherein said gate electrode and shielded electrode insulated from each other by a third insulation layer;
said gate electrode and said shielded are doped poly-silicon layers;
an implanted well region of said first conductivity type having a higher doping concentration than said epitaxial layer, disposed in a mesa between two adjacent said gate trenches, and edge of said active area to form an oxide charge balance region.
a body region of a second conductivity type formed in said mesa, above a top surface of said oxide charge region; and
a source region of said first conductivity type formed near a top surface of said body region and adjacent to said gate electrode.

12. The trench MOSFET of claim 11 further comprising a trenched source-body contact filled with a contact metal plug and penetrating through said source region and extending into said body region; and a body contact doped region of said second conductivity type within said body region and surrounding at least bottom of said trenched source-body contact underneath said source region, wherein said body contact doped region has a higher doping concentration than said body region; and
said contact metal plug is a tungsten metal layer padded by a barrier metal layer of TiMN or Co/TiN.

13. The trench MOSFET of claim 11 wherein said termination further comprising a guard ring connected with said source region and said body region, wherein said guard ring of said second conductivity type have junction depths greater than said body region.

14. The trench MOSFET of claim 11 wherein said termination further comprising a termination area which comprising multiple floating said body regions having floating voltage in a termination area wherein said multiple floating body regions having same conductivity type and junction depths as said body regions, formed simultaneously as said body regions.

15. The trench MOSFET of claim 11 further comprising a plurality of trenched source-body contact formed in an active area, each filled with a contact metal plug, penetrating through said source regions and said body regions and extending into said oxide charge balance region in said mesa; and
a body contact doped region of said second conductivity type formed along an upper portion of sidewalls of said trenched source-body contacts below said source regions, wherein said body contact doped region has a higher doping concentration than said body regions; and a Schottky diode doped region surrounding bottoms and a lower portion of sidewalls of said trenched source-body contacts below said body contact doped region, wherein said Schottky diode doped region has either said first or said second conductivity doping type; and
said contact metal plug is a tungsten metal layer padded by a barrier metal layer of Ti/TiN or Co/TiN.

16. The trench MOSFET of claim 11, wherein trench bottoms of said gate trenches are above a common interface between said substrate and said epitaxial layer.

17. The trench MOSFET of claim 11, wherein said gate trenches further touch or extend into said substrate.

18. The trench MOSF of claim 11, wherein said implanted well junction depth is deeper than depth of said gate trenches.

19. The trench MOSFET of claim 11, wherein said implanted well junction depth is shallower than depth of said gate trench.
